(19) United States
(12) Patent Application Publication
(10) Pub. No.: US 2016/0358756 A1
(43) Pub. Date: Dec. 8, 2016

(54) PLASMA PROCESSING APPARATUS

(71) Applicant: TOKYO ELECTRON LIMITED, Tokyo (JP)

(72) Inventors: Michitaka AITA, Yamanashi (JP); Jun YOSHIKAWA, Miyagi (JP); Motoshi FUKUDOME, Yamanashi (JP)

(73) Assignee: TOKYO ELECTRON LIMITED, Tokyo (JP)

(21) Appl. No.: 15/171,017

(22) Filed: Jun. 2, 2016

(30) Foreign Application Priority Data
Jun. 4, 2015 (JP) 2015-113622

(51) Int. Cl. H01J 37/32; C23C 16/455; C23C 16/50

(52) U.S. Cl. CPC H01J 37/32192; C23C 16/50; H01J 37/3244; C23C 16/455; H01L 21/67069

(57) ABSTRACT

Disclosed is a plasma processing apparatus including: a processing container that includes a bottom portion and a sidewall and defines a processing space; a microwave generator that generates microwaves; and a dielectric window attached to the sidewall of the processing container. The dielectric window is supported by a support surface formed in an upper end portion of the sidewall or a support surface formed in a conductor member disposed in the upper end portion of the sidewall, and includes a non-facing portion that does not face the processing space. Corner portions are formed on surfaces of the non-facing portion to fix a position of a node of standing waves. A distance from a sidewall corner portion to at least one of the plurality of corner portions is a distance in which a position of another node of the standing waves overlaps with a position of the sidewall corner portion.

### CROSS-REFERENCE TO RELATED APPLICATIONS

This application is based on and claims priority from Japanese Patent Application No. 2015-113622 filed on Jun. 4, 2015 with the Japan Patent Office, the disclosure of which is incorporated herein in its entirety by reference.

### TECHNICAL FIELD

Various aspects and exemplary embodiments of the present disclosure relate to a plasma processing apparatus.

### BACKGROUND

In a semiconductor manufacturing process, a plasma processing is widely performed for the purpose of deposition or etching of a thin film. In a recent plasma processing, a plasma processing apparatus using microwaves is used to generate plasma of a processing gas in some cases.

The plasma processing apparatus using microwaves uses a microwave generator to generate microwaves for plasma excitation. In addition, the plasma processing apparatus using microwaves introduces the microwaves into a processing space by a dielectric window which is attached to a sidewall of a processing container to close the processing space, and ionizes the processing gas to excite plasma. See, for example, Japanese Patent Laid-Open Publication No. 2011-003912.

### SUMMARY

According to an aspect, the present disclosure provides a plasma processing apparatus including: a processing container including a bottom portion and a sidewall and configured to define a processing space, the processing container being made of a conductor; a microwave generator configured to generate microwaves for plasma excitation; and a dielectric window attached to the sidewall of the processing container to close the processing container, and configured to introduce the microwaves into the processing space. The dielectric window is supported by a support surface formed in an upper end portion of the sidewall or a support surface formed in a conductor member disposed in the upper end portion of the sidewall, and includes a non-facing portion that does not face the processing space. A plurality of corner portions are formed on surfaces of the non-facing portion to fix a position of a node of standing waves obtained when the microwaves are reflected. A distance from a sidewall corner portion to at least one of the plurality of corner portions is a distance in which a position of another node of the standing waves overlaps with a position of the sidewall corner portion, the sidewall corner portion being formed by the support surface of the sidewall or the support surface of the conductor member, and an inner surface of the sidewall or the conductor member that faces the processing space.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating a principle part of a plasma processing apparatus according to an exemplary embodiment.

FIG. 2 is a view illustrating a slot antenna plate included in the plasma processing apparatus illustrated in FIG. 1, when viewed from the bottom.

FIG. 3 is a cross-sectional view illustrating a conductor member and a dielectric window according to the exemplary embodiment, in an enlarged scale.

FIG. 4A is a view illustrating a shape of a dielectric window of the first example.

FIG. 4B is a view for explaining a position of another node of standing waves corresponding to the dielectric window illustrated in FIG. 4A.

FIG. 5A is a view illustrating a shape of a dielectric window of the second example.

FIG. 5B is a view for explaining a position of another node of standing waves corresponding to the dielectric window illustrated in FIG. 5A.

FIG. 6A is a view illustrating a shape of a dielectric window of the third example.

FIG. 6B is a view for explaining a position of another node of standing waves corresponding to the dielectric window illustrated in FIG. 6A.

FIG. 7 is a view illustrating a simulation result of the electric field strength depending on the shape of the dielectric window.

FIG. 8A is a view illustrating a simulation result of the electric field strength when the material of the dielectric window is quartz.

FIG. 8B is a view illustrating a simulation result of the electric field strength when the material of the dielectric window is alumina.

FIG. 9 is a view illustrating a shape of a dielectric window of a modification.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the above-described technique, discharge may occur between the sidewall of the processing container and the dielectric window supported by the sidewall.

According to an aspect, the present disclosure provides a plasma processing apparatus including: a processing container including a bottom portion and a sidewall and configured to define a processing space, the processing container being made of a conductor; a microwave generator configured to generate microwaves for plasma excitation; and a dielectric window attached to the sidewall of the processing container to close the processing container, and configured to introduce the microwaves into the processing space. The dielectric window is supported by a support surface formed in an upper end portion of the sidewall or a support surface formed in a conductor member disposed in the upper end portion of the sidewall, and includes a non-facing portion that does not face the processing space. A plurality of corner portions are formed on surfaces of the non-facing portion to fix a position of a node of standing waves obtained when the microwaves are reflected. A distance from a sidewall corner portion to at least one of the plurality of corner portions is a distance in which a position of another node of the standing waves overlaps with a position of the sidewall corner portion, the sidewall corner portion being formed by the support surface of the sidewall or the support surface of the conductor member, and an inner surface of the sidewall or the conductor member that faces the processing space.

In the above-described plasma processing apparatus, assuming that a wavelength of the microwaves is λ, the distance from the sidewall corner portion to the at least one of the corner portions is within a range of n·λ/2±λ/16 (wherein n is a natural number).

In the above-described plasma processing apparatus, among the surfaces of the non-facing portion, two surfaces forming the at least one of the corner portions are formed by combining two planar surfaces.

In the above-described plasma processing apparatus, among the surfaces of the non-facing portion, two surfaces forming the at least one of the corner portions are formed by combining a planar surface and a curved surface.

In the above-described plasma processing apparatus, among the surfaces of the non-facing portion, two surfaces forming the at least one of the corner portions are formed by combining a planar surface and an inclined surface that is inclined with respect to a direction perpendicular to the planar surface.

In the above-described plasma processing apparatus, the surfaces of the non-facing portion are formed in a stepped shape including three or more corner portions as the plurality of corner portions.

According to an aspect of the plasma processing apparatus of the present disclosure, an effect capable of suppressing the discharge between the sidewall of the processing container and the dielectric window supported by the sidewall, may be achieved.

Hereinafter, exemplary embodiments of the plasma processing apparatus disclosed herein will be described in detail with reference to drawings. Meanwhile, in the respective drawings, the same or corresponding parts will be denoted by the same symbols.

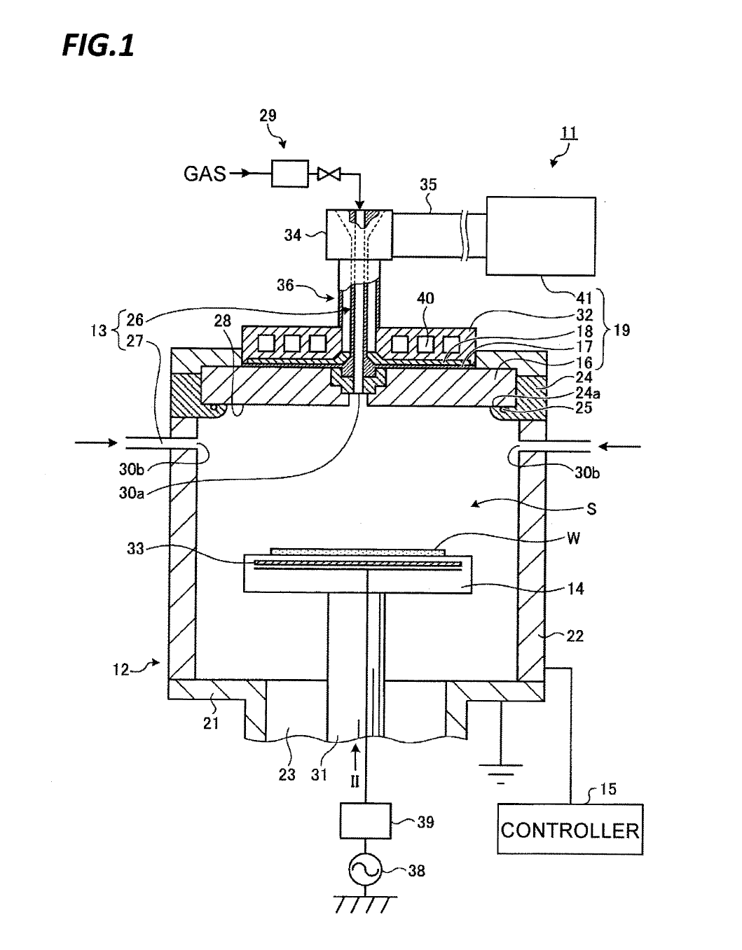

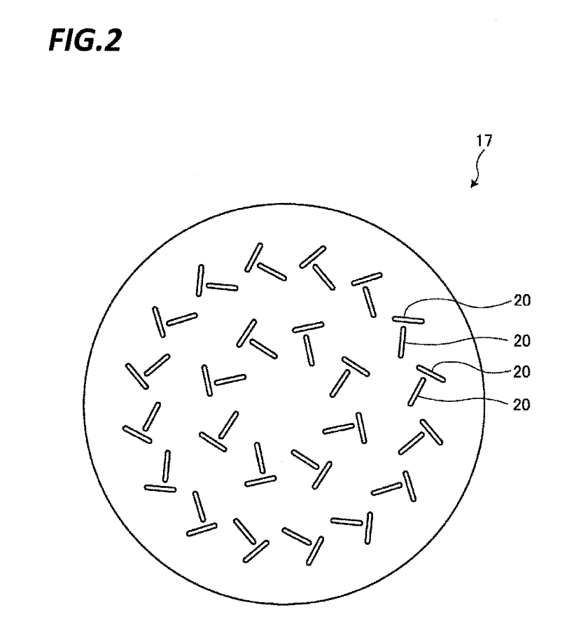

FIG. 1 is a schematic cross-sectional view illustrating a principle part of a plasma processing apparatus according to an exemplary embodiment. FIG. 2 is a view of a slot antenna plate included in the plasma processing apparatus illustrated in FIG. 1 when viewed from the bottom, that is, in the direction of the arrow II in FIG. 1. Further, in FIG. 1, hatching of some members is omitted from the viewpoint of facilitating the understanding. Further, in an exemplary embodiment, the up-and-down direction on the paper, which is indicated as the direction indicated by the arrow II in FIG. 1 or the reverse direction thereof, is referred to as a vertical direction in a plasma processing apparatus.

As illustrated in FIGS. 1 and 2, a plasma processing apparatus 11 performs a processing using plasma on a processing target substrate W, which is a processing target workpiece. Specifically, a processing such as, for example, etching, CVD, or sputtering, is performed. As the processing target substrate W, a silicon substrate may be exemplified which is used in, for example, manufacturing semiconductor devices.

The plasma processing apparatus 11 includes: a processing container 12 configured to perform a processing on a processing target substrate W by plasma therein; a gas supply section 13 configured to supply a gas for plasma excitation or a gas for plasma processing into the processing container 12; a disc-shaped holding table 14 provided in the processing container 12 and configured to hold the processing target substrate W thereon; a plasma generating mechanism 19 configured to generate plasma in the processing container 12 by using microwaves; and a controller 15 configured to control operations of the whole plasma processing apparatus 11. The controller 15 performs a control of the whole plasma processing apparatus 11 such as, for example, a gas flow rate in the gas supply section 13 and a pressure in the processing container 12.

The processing container 12 is formed of a conductor. The processing container 12 includes a bottom portion 21 positioned at a lower side of the holding table 14, and a sidewall 22 extending upward from the outer periphery of the bottom portion 21. The sidewall 22 has a substantially cylindrical shape. An exhaust hole 23 for discharging gas is provided to penetrate a portion of the bottom portion 21 of the processing container 12. The processing container 12 defines, by the sidewall 22 and the bottom portion 21, a processing space S for performing a plasma processing. The upper end portion of the sidewall 22 is opened.

A conductor member 24 is provided on the upper end portion of the sidewall 22. The conductor member 24 constitutes a part of the upper end portion of the sidewall 22. Details of the conductor member 24 will be described later. The processing container 12 is configured to be sealed by the conductor member 24, the dielectric window 16, and an 0-ring 24 interposed between the dielectric window 16 and the conductor member 24, as a seal member.

The gas supply section 13 includes a first gas supply section 26 that injects a gas toward the center of the processing target substrate W and a second gas supply section 27 that injects a gas from the outside of the processing target substrate W. A gas supply hole 30a that supplies a gas in the first gas supply section 26 is provided at a position which lies in a radial center of the dielectric window 16, and retreats inward of the dielectric window 16 from a bottom surface 28 of the dielectric window 16 serving as a facing surface that faces the holding table 14. The first gas supply section 26 supplies an inert gas for plasma excitation or a gas for plasma processing while adjusting the flow rate by a gas supply system 29 connected to the first gas supply section 26. The second gas supply section 27 includes a plurality of gas supply holes 30b that supply an inert gas for plasma excitation or a gas for plasma processing into the processing container 12, provided in a part of the upper portion of the sidewall 22. The plurality of gas supply holes 30b are provided equidistantly in the circumferential direction. The first gas supply section 26 and the second gas supply section 27 are supplied with the same kind of the inert gas for plasma excitation or the gas for plasma processing from the same gas source. Further, other gases may be supplied from the first gas supply section 26 and the second gas supply section 27 depending on a request or a control content, and the flow rate ratio thereof may be adjusted.

In the holding table 14, a high frequency wave power source 38 for radio frequency (RF) bias is electrically connected to an electrode in the holding table 14 via a matching unit 39. The high frequency power source 38 is capable of outputting high frequency waves of, for example, 13.56 MHz at a predetermined power (bias power). The matching unit 39 accommodates a matcher for matching between the impedance of the high frequency power source 38 side and the impedance of the load side (mainly, e.g., the electrode, the plasma, or the processing container 12). The matcher includes a blocking condenser for self-bias generation. During the plasma processing, a bias voltage is applied to the holding table 14 as necessary. The application of the bias voltage is performed by the control of the controller 15. In this case, the controller 15 operates as a bias voltage applying mechanism.

The holding table 14 is capable of holding the processing target substrate W thereon by an electrostatic chuck (not illustrated). Further, the holding table 14 includes a heater for heating (not illustrated), and may be set to a desired temperature by a temperature adjusting mechanism 33 provided in the holding table 14. The holding table 14 is supported by a cylindrical insulating support 31 that extends vertically upward from the lower side of the bottom portion 21. The exhaust hole 23 is provided to penetrate a part of the bottom portion 21 of the processing container 12 along the outer periphery of the cylindrical support 31. An exhaust device (not illustrated) is connected to the lower side of the annular exhaust hole 23 via an exhaust pipe (not illustrated). The exhaust device includes a vacuum pump such as, for example, a turbo molecular pump. By the exhaust device, the space within the processing container 12 may be decompressed to a predetermined pressure.

The plasma generating mechanism 19 is provided outside the processing container 12, and includes a microwave generator 41 that generates microwaves for plasma excitation. Further, the plasma generating mechanism 19 includes a dielectric window 16 that is disposed at a position facing the holding table 14. Further, the plasma generating mechanism 19 includes a slot antenna plate 17 that is provided with a plurality of slots 20 and disposed above the dielectric window 16 to radiate the microwaves to the dielectric window 16. Further, the plasma generating mechanism 19 includes a dielectric member 18 that is disposed above the slot antenna plate 17 and propagates the microwaves, which have been introduced by a coaxial waveguide 36 (to be described later), in the radial direction.

The microwave generator 41 is connected to the upper portion of the coaxial waveguide 36 that introduces the microwaves, via a waveguide 35 and a mode converter 34. For example, TE-mode microwaves generated by the microwave generator 41 are converted into TEM-mode microwaves by the mode converter 34 via the waveguide 35, which are in turn propagated via the coaxial waveguide 36.

The dielectric window 16 is substantially disc-shaped, and made of a dielectric. The dielectric window 16 is attached to the sidewall 22 of the processing container 12 through the conductor member 24 to close the processing space S. The microwaves generated by the microwave generator 41 are introduced into the processing space S in the processing container 12. Specific examples of the material of the dielectric window 16 may include quartz or alumina. Details of the dielectric window 16 will be described later.

The slot antenna plate 17 is thin plate-shaped as well as disc-shaped. As for the plurality of slots 20, as illustrated in FIG. 2, two slots 20 are paired so as to be orthogonal to each other with a predetermined space between them, and paired slots 20 are provided at predetermined intervals in the circumferential direction. In addition, a plurality of pairs of slots 20 are provided at predetermined intervals in the radial direction.

The microwaves generated by the microwave generator 41 are propagated to the dielectric member 18 through the coaxial waveguide 36. The microwaves spread radially outwardly inside the dielectric member 18 sandwiched between a cooling jacket 32 and the slot antenna plate 17, and are radiated from the plurality of slots 20 provided in the slot antenna plate 17 to the dielectric window. The cooling jacket 32 includes a circulation path 40 that allows, for example, a coolant to circulate therein, and performs a temperature adjustment of, for example, the dielectric member 18. The microwaves transmitted through the dielectric window 16 generate an electric field just below the dielectric window 16, and generate plasma within the processing container 12.

When the microwave plasma is generated in the plasma processing apparatus 11, a so-called plasma generation region having a relatively high electron temperature of the plasma is formed just below the bottom surface 28 of the dielectric window 16, specifically several centimeters below the bottom surface 28 of the dielectric window 16. In addition, in a region located at the lower side thereof, a so-called plasma diffusion region where the plasma generated in the plasma generation region is diffused is formed. The plasma diffusion region is a region having a relatively low electron temperature of the plasma, and the plasma processing is performed in this region. Therefore, the plasma processing may be efficiently performed without imparting a so-called plasma damage to the processing target substrate W during the plasma processing, and also owing to a high electron density of the plasma.

The plasma generating mechanism 19 is configured to include the dielectric window 16 that transmits high frequency waves generated by a magnetron serving as a high frequency oscillator (not illustrated) into the processing container 12, and the slot antenna plate 17 that is provided with a plurality of slots 20, and radiates the high frequency waves to the dielectric window 16. Further, the plasma generating mechanism 19 is configured such that the plasma is generated by a radial line slot antenna.

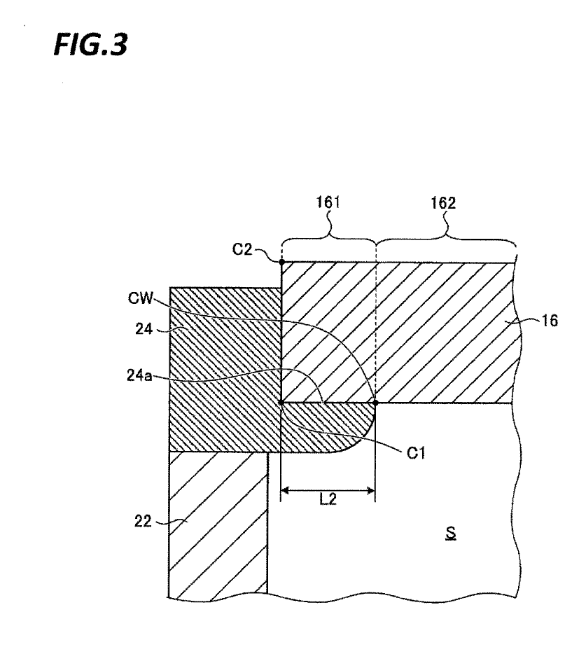

Next, details of the conductor member 24 and the dielectric window 16 illustrated in FIG. 1 will be described. FIG. 3 is a cross-sectional view illustrating a conductor member and a dielectric window according to an exemplary embodiment, in an enlarged scale.

As illustrated in FIG. 3, a support surface 24a is formed in the conductor member 24. A corner portion CW is formed by the support surface 24a of the conductor member 24 and an inner surface of the conductor member 24 facing the processing space S. Hereinafter, the corner portion CW formed by the support surface 24a of the conductor member 24 and the inner surface of the conductor member 24 facing the processing space S will be referred to as the “sidewall corner portion CW.”

The dielectric window 16 includes a non-facing portion 161 which is supported by the support surface 24a of the conductor member 24 and does not face the processing space S, and a facing portion 162 which is not supported by the support surface 24a of the conductor member 24 and faces the processing space S.

A corner portion C1 and a corner portion C2 are formed on the surfaces of the non-facing portion 161. The corner portion C1 and the corner portion C2 fix a position of a node of standing waves obtained when the microwaves propagated through the dielectric window 16 is reflected by a conductor member around the non-facing portion 161. The “conductor member around the non-facing portion 161” refers to, for example, the conductor member 24.

In an exemplary embodiment, a distance from the sidewall corner portion CW to at least one of the corner portion C 1 and the corner portion C2 is a distance in which a position of another node of the standing waves overlaps with the position of the sidewall corner portion CW. Here, the term “another node of the standing waves” refers to a node other than the node fixed by the corner portion C1 and the corner portion C2 among the nodes of the standing waves obtained when the microwaves propagated through the dielectric window 16 is reflected by a conductor member around the non-facing portion 161. Specifically, assuming that a wavelength of the microwaves propagated through the dielectric window 16 is λ, the distance from the sidewall corner portion CW to the at least one of the corner portion C1 and the corner portion C2 is within a range of n·λ/12±λ/6 (here, n is a natural number). Hereinafter, descriptions will be made on a control example of the position of another node of the standing waves along the shape of the non-facing portion 161 of the dielectric window 16.

### FIRST EXAMPLE

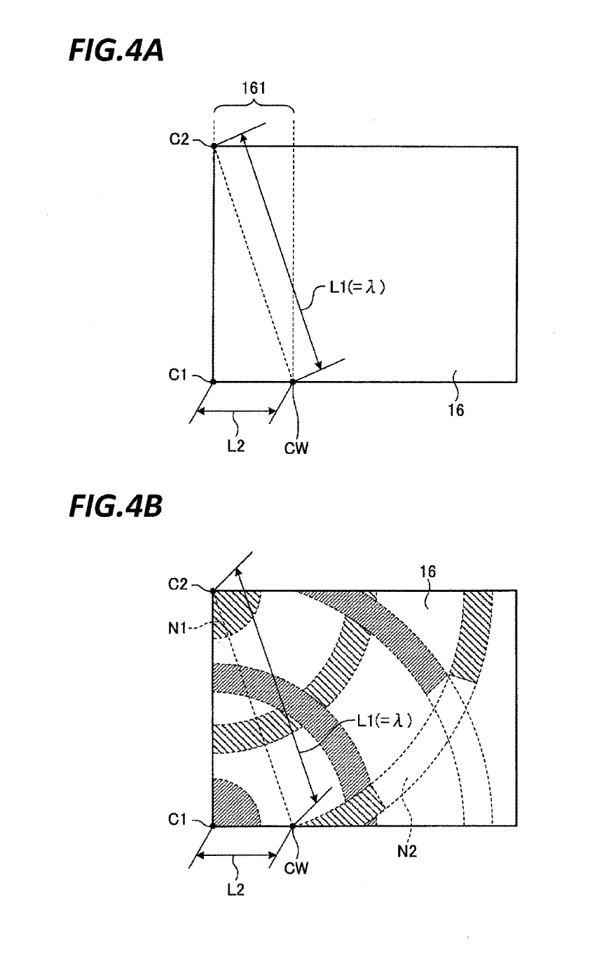

FIG. 4A is a view illustrating a shape of a dielectric window of the first example. As illustrated in FIG. 4A, in the dielectric window 16 of the first example, among the surfaces of the non-facing portion 161, two surfaces forming the corner portion C1 or the corner portion C2 are formed by combining two planar surfaces. Specifically, among the surfaces of the non-facing portion 161, two surfaces forming the corner portion C1 are formed by combining a planar surface in contact with the support surface 24a of the conductor member 24 and a planar surface perpendicular to the support surface 24a of the conductor member 24. In addition, among the surfaces of the non-facing portion 161, two surfaces foaming the corner portion C2 are formed by combining a planar surface in parallel with the support surface 24a of the conductor member 24 and a planar surface perpendicular to the support surface 24a of the conductor member 24. And, a distance L1 from the sidewall corner portion CW of the conductor member 24 to the corner portion C2 is λ.

FIG. 4B is a view for explaining a position of another node of standing waves corresponding to the dielectric window illustrated in FIG. 4A. When the distance L1 from the sidewall corner portion CW of the conductor member 24 to the corner portion C2 is λ, a position of another node N2 of the standing waves in which a position of a node N1 is fixed by the corner portion C2 overlaps with the position of the sidewall corner portion CW, as illustrated in FIG. 4B. Therefore, the electric field strength of the dielectric window 16 is reduced in the vicinity of the sidewall corner portion CW. As a result, discharge between the sidewall 22 of the processing container 22 and the dielectric window 16 supported by the sidewall 22 is suppressed.

### SECOND EXAMPLE

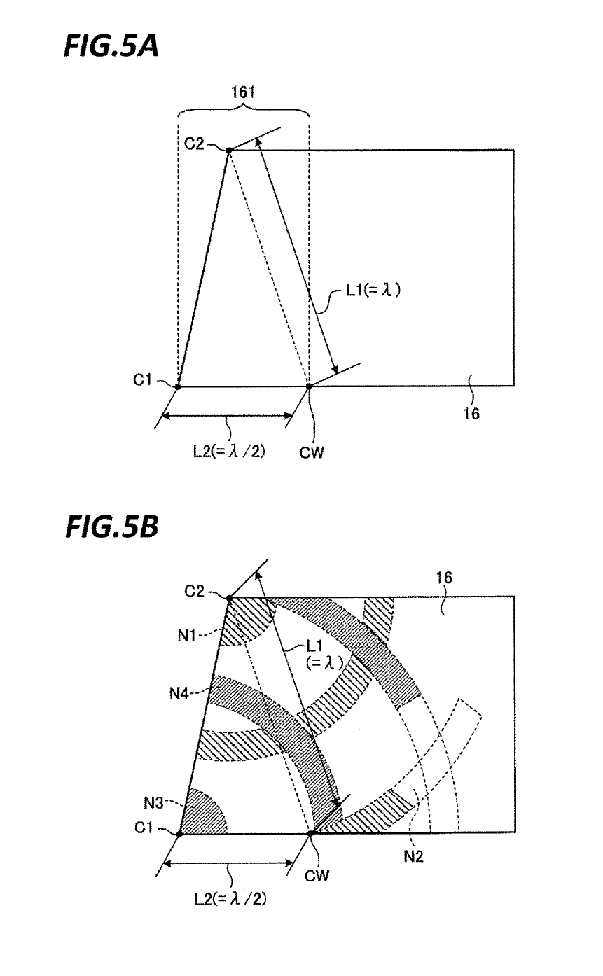

FIG. 5A is a view illustrating a shape of a dielectric window of the second example. As illustrated in FIG. 5A, in the dielectric window 16 of the second example, among the surfaces of the non-facing portion 161, two surfaces forming the corner portion C1 or the corner portion C2 are formed by combining a planar surface and an inclined surface that is inclined with respect to a direction perpendicular to the planar surface. Specifically, among the surfaces of the non-facing portion 161, two surfaces forming the corner portion C1 are formed by combining a planar surface in contact with the support surface 24a of the conductor member 24 and an inclined surface that is inclined with respect to a direction perpendicular to the planar surface. In addition, among the surfaces of the non-facing portion 161, two surfaces forming the corner portion C2 are formed by combining a planar surface in parallel with the support surface 24a of the conductor member 24 and an inclined surface that is inclined with respect to a direction perpendicular to the planar surface. And, a distance L1 from the sidewall corner portion CW of the conductor member 24 to the corner portion C2 is λ, and a distance L2 from the sidewall corner portion CW of the conductor member 24 to the corner portion C1 is λ/2.

FIG. 5B is a view for explaining a position of another node of standing waves corresponding to the dielectric window illustrated in FIG. 5A. When the distance L1 from the sidewall corner portion CW of the conductor member 24 to the corner portion C2 is λ, a position of another node N2 of the standing waves in which a position of a node N1 is fixed by the corner portion C2 overlaps with the position of the sidewall corner portion CW, as illustrated in FIG. 5B. When the distance L2 from the sidewall corner portion CW of the conductor member 24 to the corner portion C1 is 212, a position of another node N4 of the standing waves in which a position of a node N3 is fixed by the corner portion C1 overlaps with the position of the sidewall corner portion CW, as illustrated in FIG. 5B. Therefore, the electric field strength of the dielectric window 16 is reduced in the vicinity of the sidewall corner portion CW. As a result, discharge between the sidewall 22 of the processing container 22 and the dielectric window 16 supported by the sidewall 22 is suppressed.

### THIRD EXAMPLE

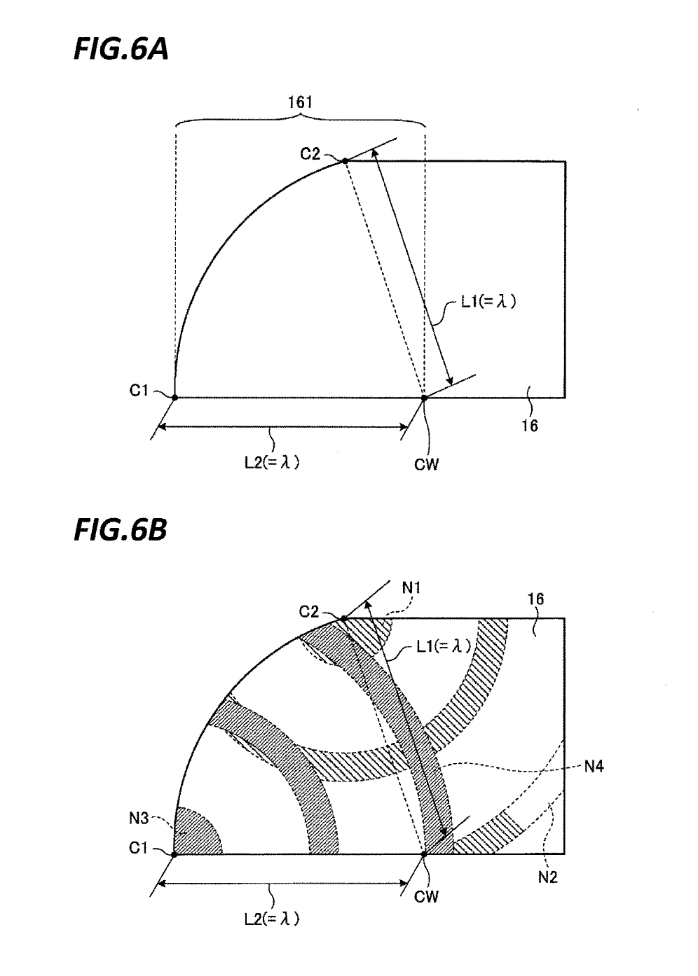

FIG. 6A is a view illustrating a shape of a dielectric window of the third example. As illustrated in FIG. 6A, in the dielectric window 16 of the first example, among the surfaces of the non-facing portion 161, two surfaces forming the corner portion C1 or the corner portion C2 are formed by combining a planar surface and a curved surface. Specifically, among the surfaces of the non-facing portion 161, two surfaces forming the corner portion C1 are formed by combining a planar surface in contact with the support surface 24a of the conductor member 24 and a curved surface having a radius of curvature of λ. In addition, among the surfaces of the non-facing portion 161, two surfaces forming the corner portion C2 are formed by combining a planar surface in parallel with the support surface 24a of the conductor member 24 and a curved surface having a radius of curvature of λ. And, a distance L1 from the sidewall corner portion CW of the conductor member 24 to the corner portion C2, and a distance L2 from the sidewall corner portion CW of the conductor member 24 to the corner portion C1 are all λ.

FIG. 6B is a view for explaining a position of another node of standing waves corresponding to the dielectric window illustrated in FIG. 6A. When the distance L1 from the sidewall corner portion CW of the conductor member 24 to the corner portion C2 is λ, a position of another node N2 of the standing waves in which a position of a node N1 is fixed by the corner portion C2 overlaps with the position of the sidewall corner portion CW, as illustrated in FIG. 6B. In addition, when the distance L2 from the sidewall corner portion CW of the conductor member 24 to the corner portion C1 is λ, a position of another node N4 of the standing waves in which a position of a node N3 is fixed by the corner portion C1 overlaps with the position of the sidewall corner portion CW, as illustrated in FIG. 6B. Therefore, the electric field strength of the dielectric window 16 is reduced in the vicinity of the sidewall corner portion CW. As a result, discharge between the sidewall 22 of the processing container 22 and the dielectric window 16 supported by the sidewall 22 is suppressed.

(Simulation Result of Electric Field Strength Depending on Shape of Dielectric Window)

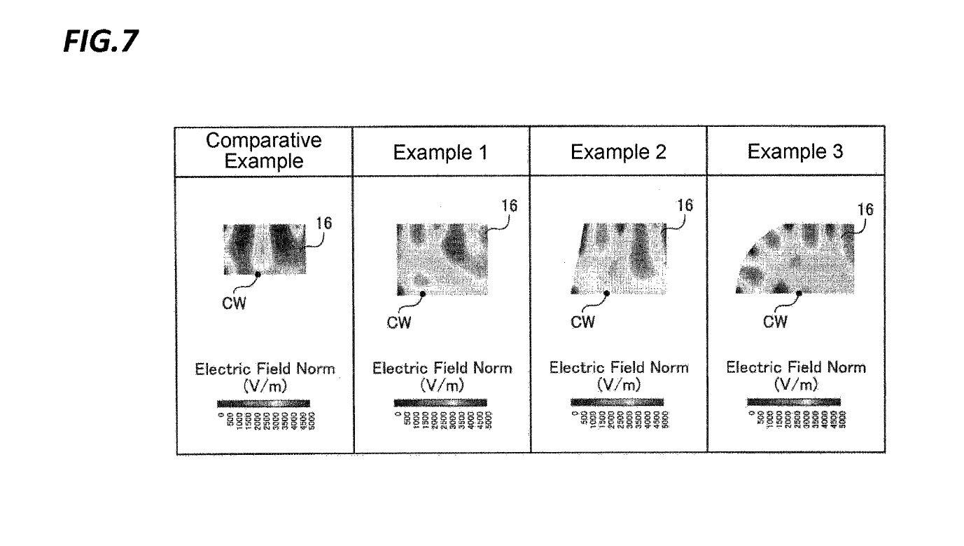

FIG. 7 is a view illustrating a simulation result of the electric field strength depending on the shape of the dielectric window. In FIG. 7, “Example 1” is a view illustrating a simulation result of the electric field strength in the dielectric window 16 corresponding to the first example of the shape of the dielectric window 16. “Example 2” is a view illustrating a simulation result of the electric field strength in the dielectric window 16 corresponding to the second example of the shape of the dielectric window 16. “Example 3” is a view illustrating a simulation result of the electric field strength in the dielectric window 16 corresponding to the third example of the shape of the dielectric window 16. Meanwhile, “Comparative Example” is a view illustrating a simulation result of the electric field strength in the dielectric window 16 in a case where the distance from the sidewall corner portion CW to at least one of the corner portion C1 and the corner portion C2 is out of the range of n·λ/2±λ/16.

As is clear from the simulation result of FIG. 7, in the example in which the distance from the sidewall corner portion CW to at least one of the corner portion C1 and the corner portion C2 is within the range of n·λ/2±λ/16, the electric field strength of the dielectric window 16 in the vicinity of the sidewall corner portion CW is reduced, as compared with the comparative example in which the distance from the sidewall corner portion CW to at least one of the corner portion C1 and the corner portion C2 is out of the range of n·λ/2±λ/16.

(Simulation Result of Electric Field Strength Depending on Material of Dielectric Window)

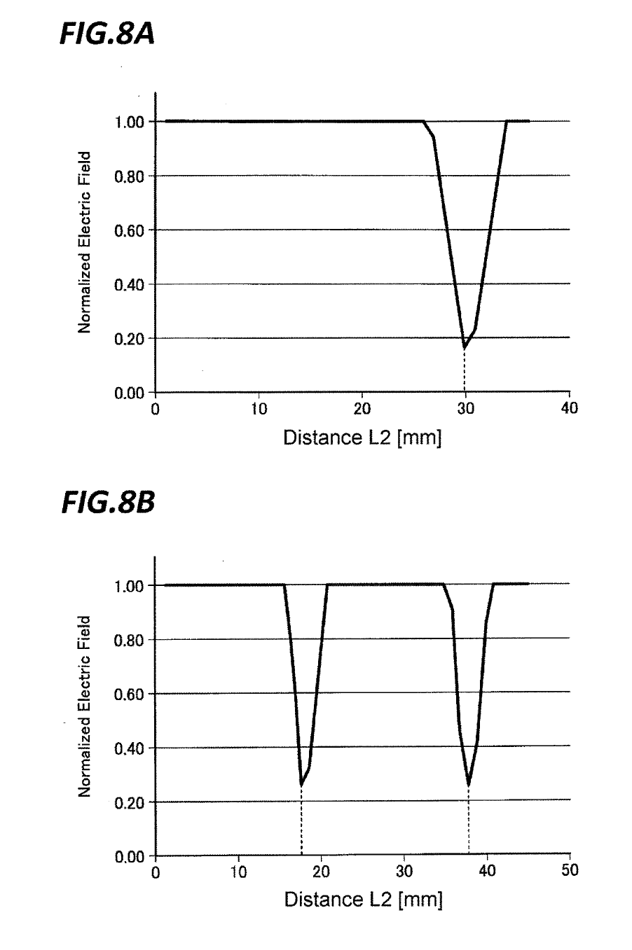

FIG. 8A is a view illustrating a simulation result of the electric field strength when the material of the dielectric window is quartz. The shape of the dielectric window 16 in the simulation illustrated in FIG. 8A is set as the one in the first example of the shape of the dielectric window 16. Further, the thickness of the dielectric window 16 in the simulation illustrated in FIG. 8A is set to 2 mm. Further, in the graph illustrated in FIG. 8A, the horizontal axis represents the distance L2 [mm] from the sidewall CW of the conductor member 24 to the corner portion C1, and the vertical axis represents an electric field in the dielectric window 16 normalized to the maximum value. In addition, in a case where the dielectric window 16 is quartz, the wavelength (λ) propagated through the dielectric window 16 is about 62.8 mm.

As illustrated in FIG. 8A, when the distance L2 was within a range of 31.2 mm±4 mm (i.e., when the distance L2 was within the range of λ/2±λ/16), the electric field strength in the dielectric window 16 was changed from 1.00 to about 0.17. That is, it has been found that, when the distance L2 is within the range of λ/2±λ/16, the electric field strength in the dielectric window 16 may be reduced by about 83%.

FIG. 8B is a view illustrating a simulation result of the electric field strength when the material of the dielectric window is alumina. The shape of the dielectric window 16 in the simulation illustrated in FIG. 8B is set as the one in the first example of the shape of the dielectric window 16. Further, the thickness of the dielectric window 16 in the simulation illustrated in FIG. 8B is set to 2 mm. Further, in the graph illustrated in FIG. 8B, the horizontal axis represents the distance L2 [mm] from the sidewall CW of the conductor member 24 to the corner portion C1, and the vertical axis represents an electric field in the dielectric window 16 normalized to the maximum value. In addition, in a case where the dielectric window 16 is alumina, the wavelength (λ) propagated through the dielectric window 16 is about 39 mm.

As illustrated in FIG. 8B, when the distance L2 was within a range of 19.6 mm±2.5 mm or 39.2 mm±2.5 mm (i.e., when the distance L2 was within the range of λ/2±λ/16 or λ±λ/16), the electric field strength in the dielectric window 16 was changed from 1.00 to about 0.25. That is, it has been found that, when the distance L2 is within the range of λ/2±λ/16 or λ+λ/16, the electric field strength in the dielectric window 16 may be reduced by about 75%.

As such, according to the plasma processing apparatus 11 of an exemplary embodiment, the distance from the sidewall corner portion CW of the conductor member 24 disposed in the upper end portion of the sidewall 22 of the processing container 12 to at least one of the plurality of corner portions formed on the surfaces of the non-facing portion 161 of the dielectric window 16 is a distance in which a position of another node of the standing waves overlaps with the position of the sidewall corner portion CW. Therefore, the electric field strength of the dielectric window 16 is reduced in the vicinity of the sidewall corner portion CW. As a result, discharge between the sidewall 22 of the processing container 22 and the dielectric window 16 supported by the sidewall 22 is suppressed.

Further, in the above-described exemplary embodiment, the non-facing portion 161 of the dielectric window 16 is supported by the support surface formed in the conductor member 24 disposed in the upper end portion of the sidewall 22 of the processing container 12, but the present disclosure is not limited thereto. For example, the non-facing portion 161 of dielectric window 16 may be supported by a support surface formed in the upper end portion of the sidewall 22 of the processing container 12. In this case, the distance from the sidewall corner portion, which is formed by the support surface of the sidewall 22, and the inner surface of the sidewall 22 that faces the processing space S, to at least one of the plurality of corner portions formed on the surfaces of the non-facing portion 161 of the dielectric window 16 is a distance in which a position of another node of the standing waves overlaps with the position of the sidewall corner portion CW.

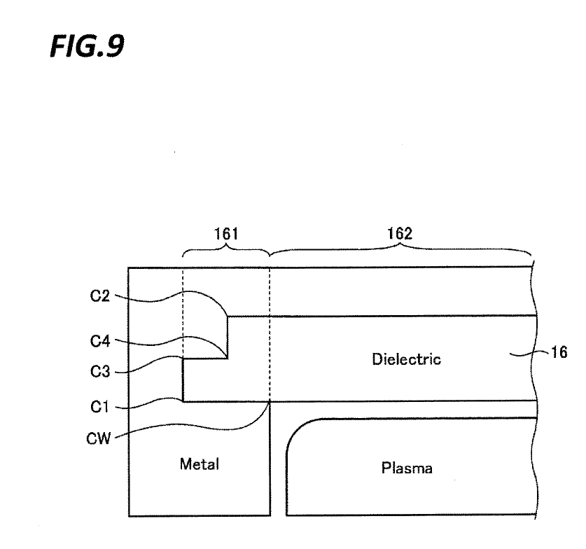

Further, in the above-described exemplary embodiment, two corner portions (i.e., the corner portion C1 and the corner portion C2) are formed on the surfaces of the non-facing portion 161 of the dielectric window 16, but the present disclosure is not limited thereto. For example, the surfaces of the non-facing portion 161 of the dielectric window 16 may be formed in a stepped shape including three or more corner portions (e.g., corner portions C1 to C4), as illustrated in FIG. 9. In this case, the distance from the sidewall corner portion CW of the conductor member 24 to at least one of the corner portions C1 to C4 formed on the surfaces of the non-facing portion 161 of the dielectric window 16 is a distance in which a position of another node of the standing waves overlaps with the position of the sidewall corner portion CW. Further, FIG. 9 is a view illustrating a shape of a dielectric window of a modification.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container including a bottom portion and a sidewall and configured to define a processing space, the processing container being made of a conductor;
a microwave generator configured to generate microwaves for plasma excitation; and
a dielectric window attached to the sidewall of the processing container to close the processing container, and configured to introduce the microwaves into the processing space,
wherein the dielectric window is supported by a support surface formed in an upper end portion of the sidewall or a support surface formed in a conductor member disposed in the upper end portion of the sidewall, and includes a non-facing portion that does not face the processing space,
a plurality of corner portions are formed on surfaces of the non-facing portion to fix a position of a node of standing waves obtained when the microwaves are reflected, and
a distance from a sidewall corner portion to at least one of the plurality of corner portions is a distance in which a position of another node of the standing waves overlaps with a position of the sidewall corner portion, the sidewall corner portion being formed by the support surface of the sidewall or the support surface of the conductor member, and an inner surface of the sidewall or the conductor member that faces the processing space.

2. The plasma processing apparatus of claim 1, wherein, assuming that a wavelength of the microwaves is λ, the distance from the sidewall corner portion to the at least one of the corner portions is within a range of n·λ/2±λ/16 (here, n is a natural number).

3. The plasma processing apparatus of claim 1, wherein, among the surfaces of the non-facing portion, two surfaces forming the at least one of the corner portions are formed by combining two planar surfaces.

4. The plasma processing apparatus of claim 1, wherein, among the surfaces of the non-facing portion, two surfaces forming the at least one of the corner portions are formed by combining a planar surface and a curved surface.

5. The plasma processing apparatus of claim 1, wherein, among the surfaces of the non-facing portion, two surfaces forming the at least one of the corner portions are formed by combining a planar surface and an inclined surface that is inclined with respect to a direction perpendicular to the planar surface.

6. The plasma processing apparatus of claim 1, wherein the surfaces of the non-facing portion are formed in a stepped shape including three or more corner portions as the plurality of corner portions.
